(19) United States
(12) Patent Application Publication
(10) Pub. No.: US 2025/0300063 A1
(43) Pub. Date: Sep. 25, 2025

(54) ELECTRONIC COMPONENT DEVICE AND METHOD OF PRODUCING ELECTRONIC COMPONENT DEVICE

(71) Applicant: RESONAC CORPORATION, Minato-ku, Tokyo (JP)

(72) Inventor: Tomoaki SHIBATA, Chiyoda-ku, Tokyo (JP)

(21) Appl. No.: 18/859,182

(22) PCT Filed: Aug. 5, 2022
(86) PCT No.: PCT/JP2022/030176

§ 371 Date: Oct. 23, 2024

(51) Int. Cl. H01L 23/498; C09D 5/24; C09D 163/00; H01L 21/56; H01L 23/31; H01L 25/16

(52) U.S. Cl. CPC H01L 23/49894; C09D 5/24; C09D 163/00; H01L 21/56; H01L 23/3128; H01L 23/49816; H01L 25/167

(57) ABSTRACT

An electronic component device, includes: a redistribution layer, an electronic circuit chip and an optical circuit chip disposed on the redistribution layer, and a first sealing layer sealing the electronic circuit chip and the optical circuit chip, wherein the first sealing layer has an opening on an opposite side from a side of the redistribution layer, and a position of the opening at least partially overlaps with a position of the optical circuit chip.

### TECHNICAL FIELD

The present disclosure relates to an electronic component device and a method of producing electronic component device

### BACKGROUND ART

In recent years, a concept of co-packaged optics, which combines an optical circuit chip and an electronic circuit chip for controlling the optical circuit chip into a single package, has been gaining popularity for applications in high-speed optical communications, HPC (High Performance Computing) or the like. This makes it possible to achieve high speed, large capacity, low power consumption, miniaturization, or the like.

Typically, the optical circuit chip and the electronic circuit chip are packaged separately and then mounted on a substrate. However, from the viewpoint of productivity, high-speed transmission, power saving, miniaturization or the like, the optical circuit chip and the electronic circuit chip are provided on a redistribution layer, packaged together, and then mounted on a substrate (see Non-Patent Document 1: “FOWLP and Si-Interposer for High-Speed Photonic Packaging”, Lim Teck Guan, Eva Wai Leong Ching, Jong Ming Ching, Loh Woon Leng, David Ho Soon Wee and Surya Bhattacharya (2021 IEEE 71st Electronic Components and Technology Conference (ECTC))).

### SUMMARY OF INVENTION

The electronic component device disclosed in Non-Patent Document 1 has been improved in terms of productivity, high-speed transmission, power saving, miniaturization or the like, but it has become apparent that there is room for improvement in thermal conductivity as an amount of heat generated by chips is increasing.

The problem that one embodiment in the present disclosure aims to solve has been made in consideration of the above circumstances, and is to provide an electronic component device with excellent thermal conductivity, and a method of producing an electronic component device.

### Solution to Problem

<1> An electronic component device, including:
a redistribution layer;
an electronic circuit chip and an optical circuit chip disposed on the redistribution layer; and
a first sealing layer sealing the electronic circuit chip and the optical circuit chip, in which:
the first sealing layer has an opening on an opposite side from a side of the redistribution layer, and
a position of the opening at least partially overlaps with a position of the optical circuit chip.
<2> The electronic component device according to <1>, further including, on an opposite side of the redistribution layer from a side of the electronic circuit chip and the optical circuit chip:
a solder ball,
a second sealing layer sealing the solder ball, and
a substrate.
<3> The electronic component device according to <1> or <2>, in which the redistribution layer includes a resin layer containing a cured product of a photosensitive resin composition, and a distribution.
<4> The electronic component device according to <3>, in which the photosensitive resin composition includes an alkali-soluble resin having a phenolic hydroxyl group.
<5> The electronic component device according to <3>, in which the photosensitive resin composition includes at least one selected from the group consisting of a polyimide resin, a polyamideimide resin, and a polybenzoxazole resin.
<6> The electronic component device according to any one of <1> to <5>, in which the first sealing layer includes a cured product of a sealing resin composition including an epoxy resin.
<7>A method of producing an electronic component device, the method including, in this order:
preparing a laminated substrate including a support substrate and a seed layer provided on one surface of the support substrate;
forming a redistribution layer on an opposite side of the seed layer from a side of the support substrate;
providing an electronic circuit chip and an optical circuit chip, on an opposite side of the redistribution layer from a side of the seed layer;
forming a first sealing layer that seals the electronic circuit chip and the optical circuit chip; and
polishing a surface of the first sealing layer at an opposite side from a side of the redistribution layer, and forming an opening at a position that at least partially overlaps with a position of the optical circuit chip.
<8> The method of producing an electronic component device according to <7>, further including:
after polishing the surface of the first sealing layer at the opposite side from the side of the redistribution layer and forming the opening at the position that at least partially overlaps with the position of the optical circuit chip, removing the support substrate.
<9> The method of producing an electronic component device according to <8>, further including:
after removing the support substrate, etching the seed layer.
<10> The method of producing an electronic component device according to <9>, further including:
after etching the seed layer, providing a solder ball, on an opposite side of the redistribution layer from a side of the electronic circuit chip and the optical circuit chip.
<11> The method of producing an electronic component device according to <10>, further including:
after providing the solder ball on the opposite side of the redistribution layer from the side of the electronic circuit chip and the optical circuit chip, providing a substrate on an opposite side of the solder ball from the side of the redistribution layer.
<12> The method of producing an electronic component device according to <11>, further including:
after providing the substrate that connects to the solder ball, forming a second sealing layer that seals the solder ball.

### Advantageous Effects of Invention

In one aspect in the present disclosure, it is possible to provide an electronic component device with excellent thermal conductivity, and a method of producing an electronic component device.

### BRIEF DESCRIPTION OF DRAWINGS

FIG. 1 is a schematic cross-sectional view showing one embodiment of an electronic component device in the present disclosure.

FIG. 2 is a schematic cross-sectional view showing one embodiment of an electronic component device in the present disclosure.

FIG. 3 is a schematic cross-sectional view for explaining one embodiment of a method of producing an electronic component device.

FIG. 4 is a schematic cross-sectional view for explaining one embodiment of a method of producing an electronic component device.

FIG. 5 is a schematic cross-sectional view for explaining one embodiment of a method of producing an electronic component device.

FIG. 6 is a schematic cross-sectional view for explaining one embodiment of a method of producing an electronic component device.

FIG. 7 is a schematic cross-sectional view for explaining one embodiment of a method of producing an electronic component device.

FIG. 8 is a schematic cross-sectional view for explaining one embodiment of a method of producing an electronic component device.

FIG. 9 is a schematic cross-sectional view for explaining one embodiment of a method of producing an electronic component device.

FIG. 10 is a schematic cross-sectional view for explaining one embodiment of a method of producing an electronic component device.

FIG. 11 is a schematic cross-sectional view for explaining one embodiment of a method of producing an electronic component device.

### DESCRIPTION OF EMBODIMENTS

Hereinafter, embodiments in the present disclosure will be described in detail. It is to be noted, however, that the present disclosure is not limited to the following embodiments. In the embodiments described below, components thereof (including element steps and the like) are not essential, unless otherwise specified. The same applies to numerical values and ranges thereof, and the present disclosure is not limited thereto.

In the present disclosure, the term “process” includes not only a process independent of other processes, but also a process that cannot be clearly distinguished from other processes, as long as the purpose of the process is achieved.

In the present disclosure, a numerical ranges indicated using “to” include the numerical values before and after “to” as the minimum and maximum values, respectively.

In the present disclosure, in the numerical ranges described step by step in the present disclosure, the upper limit or lower limit of one numerical range may be replaced with the upper or lower limit of another numerical range described step by step.

Moreover, in the numerical ranges described in the present disclosure, the upper or lower limits of the numerical ranges may be replaced with the values shown in the examples.

In the present disclosure, each component may contain multiple types of applicable substances. In a case in which a composition contains multiple substances corresponding to each component, a content or amount of each component means a total content or amount of the multiple substances present in the composition, unless otherwise specified.

In the present disclosure, the term “layer” comprehends herein not only a case in which the layer is formed over the whole observed region where the layer is present, but also a case in which the layer is formed only on part of the region.

In the present disclosure, in a case in which an embodiment is described with reference to a figure, a configuration of the embodiment is not limited to the configuration shown in the figure. In addition, a sizes of a component in each figure is conceptual, and a relative relationship between sizes of components is not limited to this.

### [Electronic Component Device]

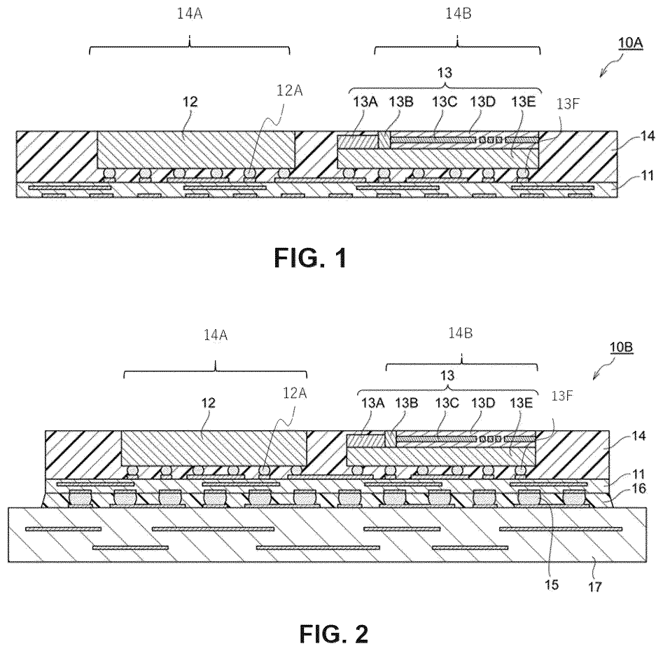

FIG. 1 is a schematic cross-sectional view showing one embodiment of an electronic component device in the present disclosure.

The electronic component device 10A in the present disclosure includes a redistribution layer 11, an electronic circuit chip 12 and an optical circuit chip 13 disposed on the redistribution layer 11, and a first sealing layer 14 sealing the electronic circuit chip 12 and the optical circuit chip 13, in which the first sealing layer 14 has an opening 14B on an opposite side from a side of the redistribution layer 11, and a position of the opening 14B at least partially overlaps with a position of the optical circuit chip 13.

In the present disclosure, the term “a position of the opening at least partially overlaps with a position of the optical circuit chip” means that there is an area on a surface of the optical circuit chip where the first sealing layer is not provided.

The first sealing layer 14 may have a plurality of openings, for example, an opening 14A, a position of the opening 14A may overlap with ae position of the electronic circuit chip 12.

The electronic circuit chip 12 may include a chip electrode 12A.

The optical circuit chip 13 may include a laser diode or photodiode 13A, a transparent resin layer 13B, a waveguide 13C, a grating 13D, an optical circuit chip substrate 13E, and a chip electrode 13F.

FIG. 2 is a schematic cross-sectional view showing another embodiment of a electronic component device in the present disclosure.

The electronic component device 10B shown in FIG. 2 further includes, on an opposite side of the redistribution layer 11 of an electronic component device 10A shown in FIG. 1 from a side of the electronic circuit chip 12 and the optical circuit chip 13, solder balls 15, a second sealing layer 16 sealing the solder balls 15, and a substrate 17.

The electronic component device in the present disclosure is not limited to the electronic component devices shown in FIGS. 1 and 2.

The electronic component device in the present disclosure has excellent thermal conductivity. The reason for the above effect is not clear, but is presumed to be as follows.

In the electronic component device in the present disclosure, on an opposite side from a side of the redistribution layer, the first sealing layer has an opening, and a position of the opening at least partially overlaps with a position of the optical circuit chip. As a result, a surface of the optical circuit chip has an area where the first sealing layer is not provided on an opposite side from a side of the redistribution layer, which makes it possible to connect a connector to the surface of the optical circuit chip and extract light. Therefore, it is presumed that the thermal conductivity is improved compared to in a case in which light is extracted from a side of the optical circuit chip. In addition, a surface of the optical circuit chip has an area where the first sealing layer is not provided, resulting in a structure in which the optical circuit chip is exposed, making it easy to dissipate heat.

Furthermore, the electronic component device in the present disclosure makes it possible to seal the optical circuit chip and the electronic circuit chip integrally by the first sealing layer on the redistribution layer, and then to mount on a substrate together, and therefore, has excellent productivity, high-speed transmission and power saving, and allows for a miniaturization compared to an electronic component device in which the electronic circuit chip and the optical circuit chip are sealed separately and then mounted respectively. Furthermore, since the chip and the substrate can be connected via the redistribution layer, the package can be made smaller than conventional packages that use wire bonding or the like.

The electronic component device in the present disclosure may further include, on an opposite side of the redistribution layer from a side of the electronic circuit chip and the optical circuit chip, a solder ball, a second sealing layer sealing the solder ball, and a substrate.

The electronic component device in the present disclosure may include a heat sink on at least one surface of the electronic circuit chip or the optical circuit chip.

### (Redistribution Layer)

The redistribution layer can include a distribution and a resin layer. In the redistribution layer, the distribution may be present on the surface of the resin layer, may be present inside the resin layer, or may be present on the surface and inside the resin layer.

The distribution in the redistribution layer preferably extends outward beyond an outline of the electronic circuit chip and the optical circuit chip.

The distribution having the above configuration can electrically connect chip electrodes included in the electronic circuit chip and the optical circuit chip to the solder balls.

The distribution may contain one or more types of metal. The metal is not particularly limited, and the metal commonly used to constitute a distribution in the redistribution layer may be used. Examples of the metal include copper, silver, gold, and aluminum.

The resin layer may contain a cured product of a photosensitive resin composition.

The photosensitive resin composition is not particularly limited, and may be appropriately selected from conventionally known compositions, specifically, an alkali-soluble resin having a phenolic hydroxyl group, an acrylic resin, a polyimide resin, a polyamideimide resin, a polybenzoxazole resin, or the like. The photosensitive resin composition may be positive or negative type.

From the viewpoint of safety, reduction of environmental load or the like, it is preferable that the photosensitive resin composition contains an alkali-soluble resin having a phenolic hydroxyl group. In the present disclosure, “alkali-soluble” means that a resin is soluble in an alkaline solution, for example, a 2.38% by mass aqueous solution of tetramethylammonium hydroxide. From the viewpoint of sensitivity, it is preferable that the photosensitive resin composition contains a photosensitizer. Furthermore, from the viewpoint of heat resistance reliability, the photosensitive resin composition may contain a thermal crosslinking agent. Furthermore, from the viewpoint of impact resistance, the photosensitive resin composition may contain an acrylic resin.

From the viewpoint of mechanical reliability and thermal reliability, the resin layer preferably has an elastic modulus of from 1 GPa to 5 GPa, and more preferably from 2 GPa to 3 GPa.

From the viewpoint of mechanical reliability and thermal reliability, the resin layer preferably has a linear expansion coefficient (α1) of from 20 ppm/° C. to 100 ppm/° C., and more preferably from 20 ppm/° C. to 60 ppm/° C.

From the viewpoint of mechanical reliability and thermal reliability, the resin layer preferably has a glass transition temperature of from 200° C. to 400° C., and more preferably from 250° C. to 350° C.

From the viewpoint of mechanical reliability and thermal reliability, the resin layer preferably has a breaking elongation of from 20% to 80%, and more preferably from 40% to 80%.

Note that the elastic modulus and breaking elongation are values at room temperature (25° C.).

The elastic modulus and breaking elongation are measured by a tensile test.

The linear expansion coefficient and glass transition temperature are measured by TMA (Thermal Mechanical Analysis).

A weight average molecular weight of the alkali-soluble resin is not particularly limited, and may be from 500 to 500,000.

In the present disclosure, the weight average molecular weight and number average molecular weight are polystyrene-equivalent weight average molecular weights measured by gel permeation chromatography (GPC).

A content of the alkali-soluble resin with respect to a total amount of the photosensitive resin composition is preferably from 50% by mass to 80% by mass, and more preferably from 55% by mass to 75% by mass.

In addition, from the viewpoint of heat resistance reliability, it is preferable that the photosensitive resin composition contains at least one resin selected from the group consisting of a polyimide resin, a polyamideimide resin, and a polybenzoxazole resin.

From the viewpoint of thermal shock resistance, compatibility with an alkali-soluble resin, developability or the like, a weight average molecular weight of the polyimide resin, the polyamideimide resin and the polybenzoxazole resin is preferably from 10,000 to 200,000, more preferably from 10,000 to 150,000, and even more preferably from 10,000 to 100,000.

In a case in which the photosensitive resin composition contains at least one selected from the group consisting of a polyimide resin, a polyamideimide resin, and a polybenzoxazole resin, from the viewpoint of adhesion, mechanical properties, thermal shock resistance or the like, a sum of contents of the polyimide resin, the polyamideimide resin and the polybenzoxazole resin with respect to a total amount of the photosensitive resin composition is preferably from 50% by mass to 100% by mass, and more preferably from 70% by mass to 95% by mass.

Furthermore, from the viewpoint of thermal shock resistance, the photosensitive resin composition preferably contains an acrylic resin.

From the viewpoint of thermal shock resistance, compatibility with alkali-soluble resin, developability or the like, a weight-average molecular weight of the acrylic resin is preferably from 2,000 to 100,000, more preferably from 3,000 to 60,000, even more preferably from 5,000 to 50,000, and particularly preferably from 10,000 to 40,000.

In a case in which the photosensitive resin composition contains an alkali-soluble resin and an acrylic resin, from the viewpoint of adhesion, mechanical properties, thermal shock resistance or the like, a content of the acrylic resin with respect to 100 parts by mass of the alkali-soluble resin is preferably from 1 part by mass to 50 parts by mass, more preferably from 3 parts by mass to 30 parts by mass, and even more preferably from 5 parts by mass to 20 parts by mass.

The photosensitive resin composition may contain a photosensitizer. In the present disclosure, a photosensitizer means a compound that generates an acid when irradiated with light. The photosensitizer may be used singly or in combination of two or more kinds.

The photosensitizer is not particularly limited, and conventionally known ones may be used.

In a case in which the photosensitive resin composition contains an alkali-soluble resin and a photosensitizer, a content of the photosensitizer with respect to 100 parts by mass of the alkali-soluble resin is preferably from 3 to 100 parts by mass, more preferably from 5 to 50 parts by mass, and even more preferably from 5 to 30 parts by mass, from the viewpoint of a difference in dissolution speed between an exposed part and an unexposed part, a permissible range of sensitivity or the like.

The photosensitive resin composition may contain a thermal crosslinking agent. As a result, when the photosensitive resin composition is cured, the alkali-soluble resin and the thermal crosslinking agent undergo a crosslinking reaction, making it possible to cure the photosensitive resin composition at a low temperature, and improving a strength and a heat resistance of the cured product. The thermal crosslinking agent may be used singly or in combination of two or more.

In a case in which the photosensitive resin composition contains an alkali-soluble resin and the thermal crosslinking agent, a content of the thermal crosslinking agent with respect to 100 parts by mass of the alkali-soluble resin is preferably from 1 part by mass to 50 parts by mass, more preferably from 2 parts by mass to 30 parts by mass, and even more preferably from 3 parts by mass to 25 parts by mass, from the viewpoint of a development time, a permissible range of a film remaining rate at unexposed part or the like.

The photosensitive resin composition may contain one or more types of solvents. Examples of the solvent include y-butyrolactone, ethyl lactate, propylene glycol monomethyl ether acetate, benzyl acetate, n-butyl acetate, ethoxyethyl propionate, 3-methylmethoxypropionate, N-methyl-2-pyrrolidone, N,N-dimethylformamide, N,N-dimethylacetamide, dimethylsulfoxide, hexamethylphosphorylamide, tetramethylene sulfone, diethyl ketone, diisobutyl ketone, methyl amyl ketone, cyclohexanone, propylene glycol monomethyl ether, propylene glycol monopropyl ether, propylene glycol monobutyl ether, and dipropylene glycol monomethyl ether.

In a case in which the photosensitive resin composition contains a solvent, a content of the solvent with respect to a total amount of the photosensitive resin composition is not particularly limited, and may be from 20% by mass to 90% by mass.

The photosensitive resin composition may contain components other than the above-mentioned components such as alkali-soluble resins (hereinafter also referred to as “other components”).

Examples of the other components include a compound that generate acid when heated, an elastomer, a dissolution promoter, a dissolution inhibitor, a coupling agent, a surfactant, and a leveling agent.

A thickness of the redistribution layer is not particularly limited, and may be, for example, from 1 μm to 20 μm.

### (Electronic Circuit Chip and Optical Circuit Chip)

The electronic circuit chip and optical circuit chip are disposed on the redistribution layer.

From the viewpoint of productivity, high-speed transmission, power saving, miniaturization or the like, it is preferable that the electronic circuit chip and the optical circuit chip are disposed side by side in the in-plane direction on the redistribution layer.

In a case in which the electronic circuit chip and the optical circuit chip are disposed side by side in the in-plane direction on the redistribution layer, from the viewpoint of productivity, high-speed transmission, power saving, miniaturization or the like, a shortest distance between the electronic circuit chip and the optical circuit chip is preferably from 0.1 mm to 10 mm, and more preferably from 0.1 mm to 5 mm.

The electronic circuit chip and the optical circuit chip are not particularly limited, and conventionally known ones may be used.

The electronic circuit chip may include an electronic circuit chip substrate (such as a silicon substrate), a transmitting circuit and a receiving circuit which are disposed on one surface of the electronic circuit chip substrate, and a chip electrode disposed on the other surface of the electronic circuit chip substrate.

The optical circuit chip may include an optical circuit chip substrate (such as a silicon substrate), a laser diode or a photodiode which are disposed on one surface of the optical circuit chip substrate, a transparent resin layer, a waveguide, and a grating, and a chip electrode disposed on the other surface of the optical circuit chip substrate.

### (First Sealing Layer)

The electronic component device in the present disclosure includes an electronic circuit chip and a first sealing layer that seals the circuit chip.

On an opposite side of the first sealing layer from a side of the redistribution layer side, the first sealing layer has an opening, and a position of the opening at least partially overlaps with a position of the optical circuit chip.

An area where the opening and the optical circuit chip overlap may be a part of the optical circuit chip or an entire optical circuit chip, so long as light can be extracted by connecting a connector.

From the viewpoint of ease of connecting a connector, a ratio of an area of the optical circuit chip overlapped with the opening with respect to a total area of the optical circuit chip (an area of the optical circuit chip overlapped with the opening/a total area of the optical circuit chip) is preferably 0.5 or more, more preferably 0.7 or more, even more preferably 0.9 or more, and may be 1.0.

The first sealing layer may have a plurality of openings. A position of the opening may overlap with a position of the electronic circuit chip.

The first sealing layer includes a cured product of a sealing resin composition. The sealing resin composition may be a conventionally known one, and may be solid or liquid.

The sealing resin composition may include an epoxy resin, and may further include at least one selected from the group consisting of a curing agent, a curing accelerator, and an inorganic filler. The epoxy resin is not particularly limited as long as it has an epoxy group in its molecule.

The cured product of the sealing resin composition preferably has an elastic modulus of from 5 GPa to 25 GPa, and more preferably from 10 GPa to 25 GPa, from the viewpoint of mechanical reliability and thermal reliability.

The cured product of the sealing resin composition preferably has a linear expansion coefficient (α1) of from 5 ppm/° C. to 30 ppm/° C., and more preferably from 10 ppm/° C. to 25 ppm/° C., from the viewpoint of mechanical reliability and thermal reliability.

The cured product of the sealing resin composition preferably has a glass transition temperature of from 100° C. to 150° C., and more preferably from 120° C. to 150° C., from the viewpoint of mechanical reliability and thermal reliability.

Methods of measuring the elastic modulus, the linear expansion coefficient and the glass transition temperature are as described above.

An epoxy equivalent (molecular weight/number of epoxy groups) of the epoxy resin is not particularly limited. From the viewpoint of a balance of various properties such as moldability, reflow resistance and electrical reliability, the epoxy equivalent is preferably from 100 g/eq to 1000 g/eq, and more preferably from 150 g/eq to 500 g/eq.

The epoxy equivalent of the epoxy resin is a value measured by a method in accordance with JIS K 7236:2009.

In a case in which the epoxy resin is solid, its melting point or softening point is not particularly limited. From the viewpoint of moldability and reflow resistance, the melting point or softening point is preferably from 40° C. to 180° C., and from the viewpoint of handleability during preparing the sealing resin composition, it is more preferably from 50° C. to 130° C.

The melting point of the epoxy resin is a value measured by differential scanning calorimetry (DSC), and the softening point of the epoxy resin is a value measured by a method in accordance with JIS K 7234:1986 (ring and ball method).

A content of the epoxy resin in a total amount of the sealing resin composition is preferably from 2% by mass to 10% by mass, more preferably from 2.5% by mass to 7.5% by mass, and even more preferably from 3% by mass to 6.5% by mass, from the viewpoint of strength, fluidity, heat resistance, moldability or the like.

A functional group equivalent of the curing agent (e.g., hydroxyl group equivalent in the case of a phenolic curing agent) is not particularly limited. From the viewpoint of a balance of various properties such as moldability, reflow resistance and electrical reliability, it is preferably from 70 g/eq to 1000 g/eq, and more preferably from 80 g/eq to 500 g/eq.

The hydroxyl group equivalent of the phenolic curing agent is a value measured by a method in accordance with JIS K 0070:1992.

In a case in which the curing agent is a solid, its melting point or softening point is not particularly limited. From the viewpoint of moldability and reflow resistance, it is preferably from 40° C. to 180° C., and from the viewpoint of handling during preparing the sealing resin composition, it is more preferably from 50° C. to 130° C.

The melting point or softening point of the curing agent is a value measured in the same manner as the melting point or softening point of the epoxy resin.

An equivalent ratio of the epoxy resin to the curing agent, that is, a ratio of a number of functional groups in the curing agent to a number of functional groups in the epoxy resin (number of functional groups in the curing agent/number of functional groups in the epoxy resin) is not particularly limited. From the viewpoint of minimizing unreacted components respectively, it is preferably set in a range of from 0.5 to 1.5, more preferably set in a range of from 0.6 to 1.3, and even more preferably set in a range of from 0.7 to 1.2.

A type of curing accelerator is not particularly limited, and may be selected depending on a type of epoxy resin, desired properties of the sealing resin composition or the like. As the curing accelerator, a phosphorus type curing accelerator is preferable from the viewpoint of an electrical reliability of the sealing resin composition and a fluidity during molding.

A content of the curing accelerator in the sealing resin composition is not particularly limited as long as a curing acceleration effect is obtained. The content of the curing accelerator in the sealing resin composition is preferably from 0.1% by mass to 8.0% by mass, more preferably from 0.5% by mass to 5.0% by mass, and even more preferably from 1.0% by mass to 3.0% by mass, with respect to a total amount of the epoxy resin and the curing agent.

The sealing resin composition may contain an inorganic filler. By including an inorganic filler, it is possible to reduce moisture absorption and improve strength when the composition is cured. A shape of the inorganic filler is not particularly limited, and examples thereof include a powder shape, a sphere shape, and a fiber shape. Among these, a spherical shape is preferred from the viewpoint of fluidity during molding of the sealing resin composition and mold wear resistance.

### (Solder Ball)

The electronic component device in the present disclosure may include a solder ball on an opposite side of the redistribution layer from a side of the electronic circuit chip and optical circuit chip. The solder ball is electrically connected to a chip electrode of the electronic circuit chip and optical circuit chip by a distribution provided in the redistribution layer. The solder ball is also electrically connected to a distribution provided in the substrate described below. Conventionally known solder ball may be used.

### (Second Sealing Layer)

The electronic component device in the present disclosure may include a second sealing layer that seals the solder ball.

The second sealing layer includes a cured product of a sealing resin composition. The sealing resin composition used may be the same as that used to form the first sealing layer, or a different one may be used.

The second sealing layer may be provided between a substrate described below and the redistribution layer.

The second sealing layer may also be provided in a location other than between the substrate and the redistribution layer. In this case, the second sealing layer has a second opening on an opposite side from a side of the substrate of the second sealing layer, and the position of the second opening at least partially overlaps with a position of the optical circuit chip.

An area where the second opening overlaps with the optical circuit chip may be a part of the optical circuit chip or an entire optical circuit chip, as long as light can be extracted by connecting the connector.

From the viewpoint of ease of connecting a connector, a ratio of the area where the optical circuit chip overlaps with the second opening to a total area of the optical circuit chip (area where optical circuit chip overlaps with second opening/total area of optical circuit chip) is preferably 0.5 or more, more preferably 0.7 or more, even more preferably 0.9 or more, and may be 1.0.

The second sealing layer may have a plurality of second openings. A position of the second opening may overlap a position of the electronic circuit chip.

### (Substrate)

The electronic component device in the present disclosure may be provided with a substrate on an opposite side of the redistribution layer from a side of the electronic circuit chip and optical circuit chip. The substrate may be a distribution substrate including distribution, and the distribution is electrically connected to the solder ball.

Examples of a material constituting the substrate include ceramic, glass, silicon, metal oxides such as TiO₂ and SiO₂, and silicon nitride. Glass cloth impregnated with epoxy resin or the like may also be used as the substrate.

### (Heat Sink)

The electronic component device in the present disclosure may be provided with a heat sink on at least one surface of the electronic circuit chip and the optical circuit chip, thereby further improving a heat dissipation of the electronic component device.

The electronic component device in the present disclosure may be provided with a layer composed of a TIM (Thermal Interface Material), such as a thermally conductive sheet or thermally conductive grease, between the electronic circuit chip and the optical circuit chip and the heat sink.

### [Method of Producing Electronic Component Device]

A method of producing an electronic component device in the present disclosure includes, in this order:

preparing a laminated substrate including a support substrate and a seed layer provided on one surface of the support substrate (hereinafter also referred to as a “process of preparing a laminated substrate”);
forming a redistribution layer on an opposite side of the seed layer from a side of the support substrate (hereinafter also referred to as a “process of forming a redistribution layer”);
providing an electronic circuit chip and an optical circuit chip, on an opposite side of the redistribution layer from a side of the seed layer (hereinafter also referred to as a “process of providing an electronic circuit chip and an optical circuit chip”);
forming a first sealing layer that seals the electronic circuit chip and the optical circuit chip (hereinafter also referred to as a “process of forming a first sealing layer”); and
polishing a surface of the first sealing layer at an opposite side from a side of the redistribution layer, and forming an opening at a position that at least partially overlaps with a position of the optical circuit chip (hereinafter also referred to as a “process of forming an opening”).

The method of producing an electronic component device in the present disclosure may further include, after the process of forming an opening, removing the support substrate (hereinafter also referred to as a “process of removing the support substrate”). The method of producing an electronic component device in the present disclosure may further include, after the process of removing the support substrate, etching the seed layer (hereinafter also referred to as a “process of etching the seed layer”).

The method of producing an electronic component device in the present disclosure may further include, after the process of etching the seed layer, providing a solder ball on an opposite side of the redistribution layer from a side of the electronic circuit chip and the optical circuit chip (hereinafter also referred to as a “process of providing a solder ball”).

The method of producing an electronic component device in the present disclosure may further include, after the process of providing a solder ball, providing a substrate on an opposite side of the solder ball from the side of the redistribution layer (hereinafter also referred to as a “process of providing a substrate”).

The method of producing an electronic component device in the present disclosure may further include, after the process of providing a substrate, forming a second sealing layer that seals the solder ball (hereinafter also referred to as a “process of forming a second sealing layer”).

In a case in which the formed second sealing layer seals the electronic circuit chip and the optical circuit chip together with the solder ball, the method of producing an electronic component device in the present disclosure may include polishing a surface of the second sealing layer at an opposite side from a side of the substrate, and forming a second opening at a position that at least partially overlaps with a position of the optical circuit chip (hereinafter also referred to as a “process of forming a second opening”).

The method of producing an electronic component device in the present disclosure may further include providing a heat sink on at least one surface of the electronic circuit chip and the optical circuit chip (hereinafter also referred to as a “process of providing a heat sink”).

### (Process of Preparing Laminated Substrate)

The laminated substrate includes a support substrate and a seed layer provided on one surface of the support substrate.

The laminated substrate may include a temporary fixing layer and a seed layer, in this order, on at least one surface.

The support substrate may be one produced by a conventionally known method, or may be a commercially available one. For example, a glass substrate may be used as the support substrate.

A material constituting the seed layer is not particularly limited, and a conventionally known material may be used. The seed layer may be formed by plating a glass substrate with copper, titanium, or the like.

Examples of a material that can be used to form the temporary fixing layer include a resin containing non-polar component such as an acryl, a polyimide, a polybenzoxazole, a silicone and a fluorine, a resin containing a component that expand in volume or foam when exposed to heat or UV (ultraviolet light), a resin containing a component that undergoes a cross-linking reaction when exposed to heat or UV light, and a resin that generate heat when exposed to light.

A method of forming the temporary fixing layer include a spin coating, a spray coating, and a lamination.

The temporary fixing layer is removed together with the support substrate in a process of removing the support substrate, and the seed layer remains on the surface of the redistribution layer.

### (Process for Forming Redistribution Layer)

The redistribution layer is not particularly limited, and may be formed by a conventionally known method using the above-mentioned photosensitive resin composition.

In one embodiment, the redistribution layer may be formed by the following method.

First, a photosensitive resin composition is applied to a surface on a side of the seed layer of the support substrate to form a coating membrane. Next, the coating membrane is exposed to light. After exposure, an exposed portion is removed with a developer, and a non-exposed portion is heated to form a resin layer. Next, the redistribution layer may be formed by providing a distribution at the exposed portion that has been removed. After forming the coating membrane formation, exposing and providing a distribution may be repeated. In addition, drying may be performed after applying the photosensitive resin composition. For drying, a hot plate, an oven or the like may be used. A conventionally known mask may be used for exposing the coating membrane. In addition, an ultraviolet light, a visible light, a radiation or the like can be used for exposing. Examples of the developer include an aqueous solution containing an alkaline component such as sodium hydroxide, potassium hydroxide, sodium silicate, ammonia, ethylamine, diethylamine, triethylamine, triethanolamine and tetramethylammonium hydroxide; and an organic solvent such as γ-butyrolactone, ethyl lactate, propylene glycol monomethyl ether acetate, benzyl acetate, n-butyl acetate, ethoxyethyl propionate, 3-methylmethoxypropionate, N-methyl-2-pyrrolidone, N,N-dimethylformamide, N,N-dimethylacetamide, dimethylsulfoxide, hexamethylphosphorylamide, tetramethylene sulfone, diethyl ketone, diisobutyl ketone, methyl amyl ketone, cyclohexanone, propylene glycol monomethyl ether, propylene glycol monopropyl ether, propylene glycol monobutyl ether, and dipropylene glycol monomethyl ether. For heating the non-exposed portion, a quartz tube furnace, a hot plate, a rapid thermal annealer, a vertical diffusion furnace, an infrared curing furnace, an electron beam curing furnace, an oven such as a microwave curing furnace, a microwave curing device, a frequency variable microwave curing device or the like may be used.

### (Process of Providing Electronic Circuit Chip and Optical Circuit Chip)

The electronic circuit chip and the optical circuit chip may be provided by placing them on the redistribution layer and electrically connecting the distribution contained in the redistribution layer to the chip electrodes of the electronic circuit chip and the optical circuit chip. A method of connecting is not particularly limited, and may be performed by a conventionally known method.

### (Process of Forming First Sealing Layer)

A method of forming a first sealing layer is not particularly limited, and may be performed by a conventionally known method. For example, the first sealing layer may be formed using a transfer molding method, an injection molding method, a compression molding method, or a mold underfill method.

### (Process of Forming Opening)

A method of producing an electronic component device in the present disclosure includes polishing a surface of the first sealing layer at an opposite side from a side of the redistribution layer, and forming an opening at a position that at least partially overlaps with a position of the optical circuit chip.

A method of polishing is not particularly limited, and may be performed by a conventionally known method.

A number of the opening formed by polishing the first sealing layer may be one, or may be two or more. A position of the opening may overlap with a position of the electronic circuit chip.

### (Process of Removing Support Substrate)

A method of removing the support substrate is not particularly limited, and may be performed by a conventionally known method. In a case in which the laminated substrate has a temporary fixing layer, the temporary fixing layer is also removed together with the support substrate.

### (Process of Etching Seed Layer)

The seed layer may be etched by a conventional method such as spraying, swing immersion, brushing, scraping or the like.

(Process of Providing Solder ball)

A solder ball may be provided by placing them on the redistribution layer and electrically connecting it to a distribution contained in the redistribution layer.

Conventionally known solder ball may be used.

### (Process of Providing Substrate)

A substrate can be provided by contacting the substrate with the solder ball and electrically connecting a distribution included in the substrate to the solder ball.

### (Process of Forming Second Sealing Layer)

A method of forming a second sealing layer is not particularly limited, and may be performed by a conventionally known method. For example, the second sealing layer may be formed using the above-mentioned transfer molding method, injection molding method, compression molding method, mold underfill method, capillary underfill method or the like.

By using the capillary underfill method, a sealing layer may be formed only between the substrate and the redistribution layer. This makes it possible to prevent the second sealing layer from being formed on the surfaces of the electronic circuit chip and the optical circuit chip, and the process of forming a second opening may be omitted. (Process of Forming Second Opening)

In a case in which the electronic circuit chip and the optical circuit chip are sealed together with the solder ball by forming the second sealing layer, the method of producing an electronic component device in the present disclosure includes polishing a surface of the second sealing layer at an opposite side from a side of the substrate and forming a second opening at a position that at least partially overlaps with a position of the optical circuit chip.

A method of polishing is not particularly limited, and may be performed by a conventionally known method.

A number of the second opening formed by polishing the second sealing layer may be one, or maybe two or more. A position of the second opening may overlap with a position of the electronic circuit chip.

### (Process of Providing Heat Sink)

A method of producing an electronic component device in the present disclosure may further include a process of providing a heat sink on at least one surface of the electronic circuit chip and the optical circuit chip

A timing of the process of providing a heat sink is not particularly limited, and for example, it may be performed after the process of forming the opening and before the process of removing the support substrate. Alternatively, the process of providing a heat sink may be performed after the process of forming the second opening.

A conventionally known heat sink may be used as the heat sink. The heat sink may be provided on a surface of the electronic circuit chip and the optical circuit chip by using a TIM (Thermal Interface Material) such as a thermally conductive sheet or a thermally conductive grease.

Hereinafter, with reference to FIGS. 1 to 10, an embodiment of a method of producing an electronic component device in the present disclosure will be described. Note that the method of producing an electronic component device in the present disclosure is not limited to the method of producing an electronic component device shown in the following figures.

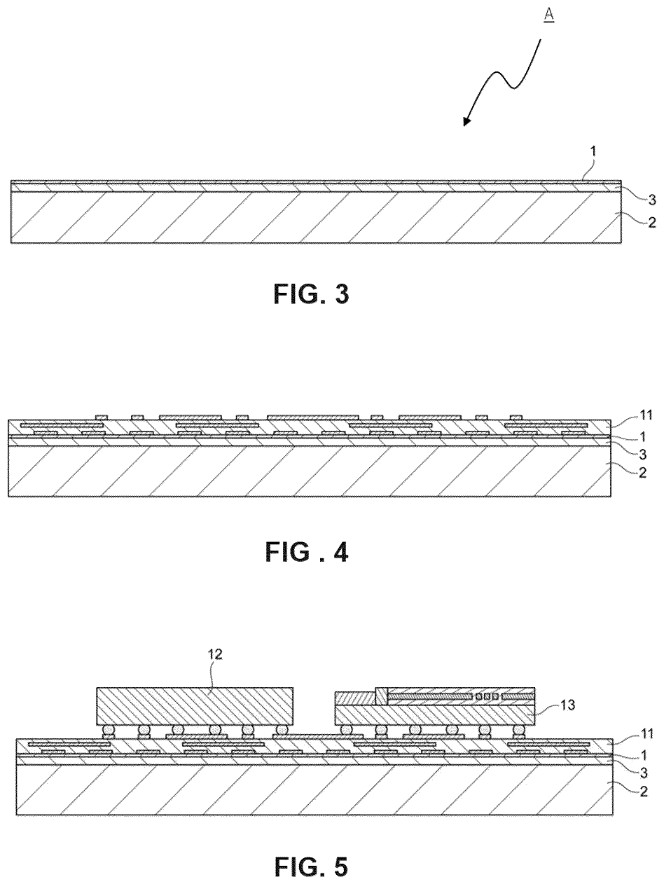

As shown in FIG. 3, the method of producing an electronic component device in the present disclosure includes preparing a laminated substrate A including a support substrate 2 and a seed layer 1 provided on one surface of the support substrate 2. The support substrate 2 includes a temporary fixing layer 3 on a side of a side of the support substrate 2 on the seed layer 1.

As shown in FIG. 4, the method of producing an electronic component device in the present disclosure includes forming a redistribution layer 11 on an opposite side of the seed layer 1 from a side of the support substrate 2

As shown in FIG. 5, the method of producing an electronic component device in the present disclosure includes providing an electronic circuit chip 12 and an optical circuit chip 13, on an opposite side of the redistribution layer 11 from a side of the seed layer 1.

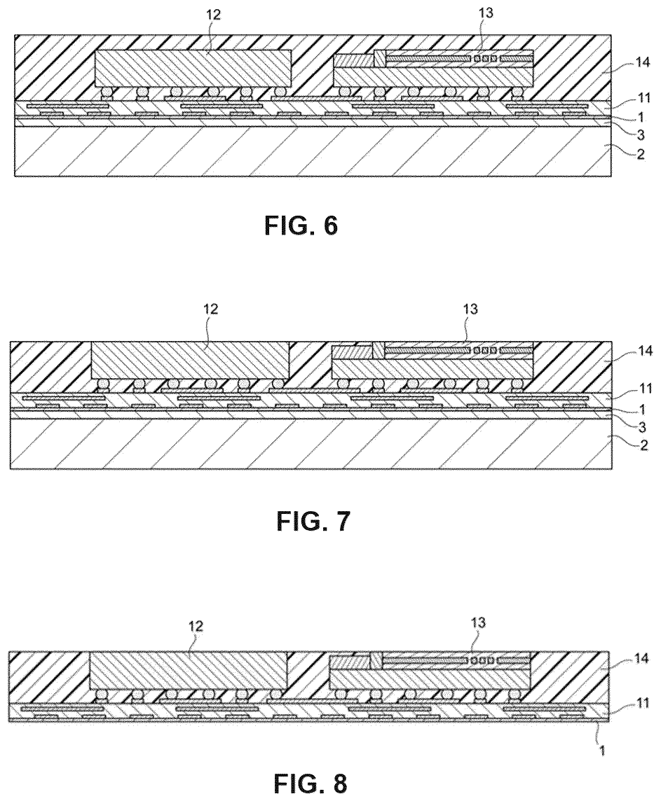

As shown in FIG. 6, the method of producing an electronic component device in the present disclosure includes forming a first sealing layer 14 that seals the electronic circuit chip 12 and the optical circuit chip 13.

As shown in FIG. 7, the method of producing an electronic component device in the present disclosure includes polishing a surface of the first sealing layer 14 at an opposite side from a side of the redistribution layer 11, and forming an opening 14 B at a position that at least partially overlaps with a position of the optical circuit chip 12.

As shown in FIG. 8, the method of producing an electronic component device in the present disclosure may further include, after forming the opening, removing the support substrate 2. As shown in FIG. 8, the temporary fixing layer 3 is removed together with the support substrate 2.

As shown in FIG. 1, the method of producing an electronic component device in the present disclosure may further include, after removing the support substrate, etching the seed layer 1. In this way, one embodiment of the electronic component device in the present disclosure may be produced.

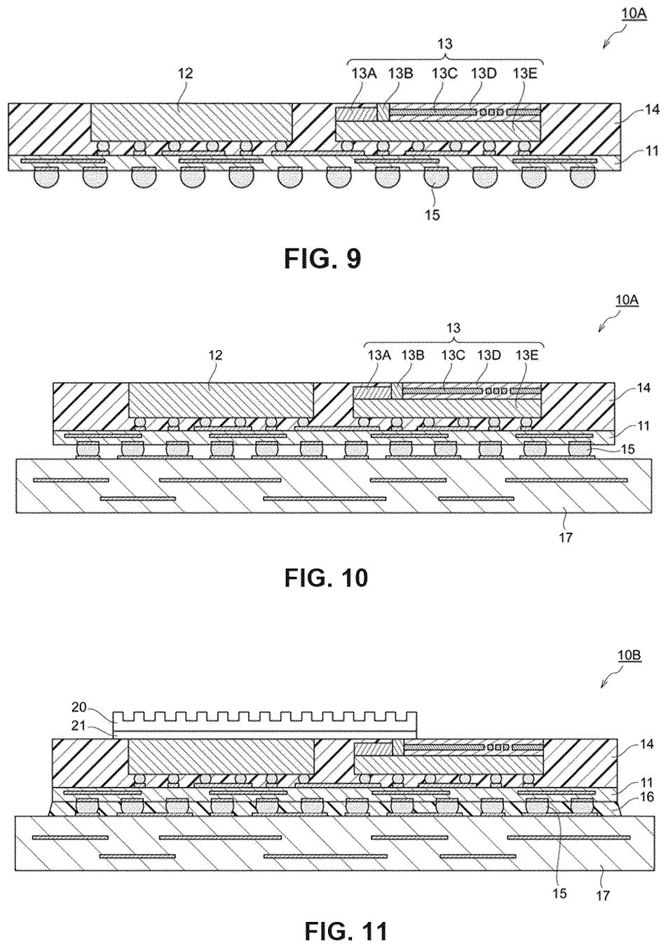

As shown in FIG. 9, the method of producing an electronic component device in the present disclosure may further include, after etching the seed layer, providing a solder ball 15, on an opposite side of the redistribution layer 11 from a side of the electronic circuit chip 12 and the optical circuit chip 13.

As shown in FIG. 10, the method of producing an electronic component device in the present disclosure may further include, after providing the solder ball, providing a substrate 17 on an opposite side of the solder ball 15 from the side of the redistribution layer 11.

As shown in FIG. 2, the method of producing an electronic component device in the present disclosure may further include, after providing the substrate, forming a second sealing layer 16 that seals the solder ball 15. In this way, one embodiment of the electronic component device in the present disclosure may be produced.

As shown in FIG. 11, the method of producing an electronic component device in the present disclosure may further include providing a heat sink 20 on at least one surface of the electronic circuit chip 12 and the optical circuit chip 13. The heat sink 20 may be provided on at least the surfaces of the electronic circuit chip 12 and the optical circuit chip 13 by TIM 21.

1. An electronic component device, comprising:
a redistribution layer;
an electronic circuit chip and an optical circuit chip disposed on the redistribution layer; and
a first sealing layer sealing the electronic circuit chip and the optical circuit chip, wherein:
the first sealing layer has an opening on an opposite side from a side of the redistribution layer, and
a position of the opening at least partially overlaps with a position of the optical circuit chip.

2. The electronic component device according to claim 1, further comprising, on an opposite side of the redistribution layer from a side of the electronic circuit chip and the optical circuit chip:
a solder ball,
a second sealing layer sealing the solder ball, and
a substrate.

3. The electronic component device according to claim 1, wherein the redistribution layer comprises a resin layer containing a cured product of a photosensitive resin composition, and a distribution.

4. The electronic component device according to claim 3, wherein the photosensitive resin composition comprises an alkali-soluble resin having a phenolic hydroxyl group.

5. The electronic component device according to claim 3, wherein the photosensitive resin composition comprises at least one selected from the group consisting of a polyimide resin, a polyamideimide resin, and a polybenzoxazole resin.

6. The electronic component device according to claim 1, wherein the first sealing layer comprises a cured product of a sealing resin composition comprising an epoxy resin.

7. A method of producing an electronic component device, the method comprising, in this order:
preparing a laminated substrate comprising a support substrate and a seed layer provided on one surface of the support substrate;
forming a redistribution layer on an opposite side of the seed layer from a side of the support substrate;
providing an electronic circuit chip and an optical circuit chip, on an opposite side of the redistribution layer from a side of the seed layer;
forming a first sealing layer that seals the electronic circuit chip and the optical circuit chip; and
polishing a surface of the first sealing layer at an opposite side from a side of the redistribution layer, and forming an opening at a position that at least partially overlaps with a position of the optical circuit chip.

8. The method of producing an electronic component device according to claim 7, further comprising:
after polishing the surface of the first sealing layer at the opposite side from the side of the redistribution layer and forming the opening at the position that at least partially overlaps with the position of the optical circuit chip, removing the support substrate.

9. The method of producing an electronic component device according to claim 8, further comprising:
after removing the support substrate, etching the seed layer.

10. The method of producing an electronic component device according to claim 9, further comprising:
after etching the seed layer, providing a solder ball, on an opposite side of the redistribution layer from a side of the electronic circuit chip and the optical circuit chip.

11. The method of producing an electronic component device according to claim 10, further comprising:
after providing the solder ball on the opposite side of the redistribution layer from the side of the electronic circuit chip and the optical circuit chip, providing a substrate on an opposite side of the solder ball from the side of the redistribution layer.

12. The method of producing an electronic component device according to claim 11, further comprising:
after providing the substrate that connects to the solder ball, forming a second sealing layer that seals the solder ball.
